(19) United States
(12) Patent Application Publication
(10) Pub. No.: US 2023/0137541 A1
(43) Pub. Date: May 4, 2023

(54) SWITCHING RECURRENT KALMAN NETWORK

(71) Applicant: Robert Bosch GmbH, Stuttgart (DE)

(72) Inventors: Giao NGUYEN, Stuttgart (DE); Chen QIU, Sindelfingen (DE); Philipp BECKER, Stuttgart (DE); Maja RUDOLPH, Madison, WI (US); Gerhard NEUMANN, Karlsruhe (DE)

(21) Appl. No.: 17/516,330

(22) Filed: Nov. 1, 2021

(51) Int. Cl. H03H 17/02; G06N 3/04; G05D 1/02

(52) U.S. Cl. CPC H03H 17/0257; G06N 3/0445; G05D 1/0223

(57) ABSTRACT

A method of controlling a device includes receiving data from a first sensor, encoding, via parameters of an encoder, the data to obtain a latent observation (wₜ) for the data and an uncertainty vector (σ_{wt}) for the latent observation, processing the latent observation with a recurrent neural network to obtain a switching variable (sₜ) which determines weights (αₜ) of a locally linear Kalman filter, processing the latent observation and the uncertainty vector with said locally linear Kalman filter to obtain updated mean of latent representation (μ_{zt}) and covariance of latent representation (Σ_{zt}) of the Kalman filter, decoding the latent representation to obtain mean (μₓₜ) and covariance of a reconstruction of the data (Σₓₜ) and outputting the reconstruction at a time t.

### TECHNICAL FIELD

This disclosure relates generally to a system and method to estimate unknown variables given measurements observed over time in a machine learning system.

### BACKGROUND

A linear quadratic estimation (LQE) commonly referred to as a Kalman filter is an algorithm that produces estimates of unknown variables based on a series of measurements observed over time. The measurements observed over time may include noise and other inaccuracies, and thus the estimates of the unknown variables may be more accurate than those based on a single measurement alone as the estimation includes a joint probability distribution over the variables for each timeframe.

### SUMMARY

A method of controlling a device includes receiving data from a first sensor, encoding, via parameters of an encoder, the data to obtain a latent observation (wₜ) for the data and an uncertainty vector (σ_{wt}) for the latent observation, processing the latent observation with a recurrent neural network to obtain a switching variable (sₜ) which determines weights (αₜ) of a locally linear Kalman filter, processing the latent observation and the uncertainty vector with said locally linear Kalman filter to obtain updated mean of latent representation (μ_{zt}) and covariance of latent representation (Σ_{zt}) of the Kalman filter, decoding the latent representation to obtain mean (μₓₜ) and covariance of a reconstruction of the data (Σₓₜ) and outputting the reconstruction at a time t.

A device control system includes a controller. The controller may be configured to, receive data from a first sensor, encode, via parameters of an encoder, the data to obtain a latent observation (wₜ) for the data and an uncertainty vector (σ_{wt}) for the latent observation, process the latent observation with a recurrent neural network to obtain a switching variable (sₜ) which determines weights (αₜ) of a locally linear Kalman filter, process the latent observation and the uncertainty vector with said locally linear Kalman filter to obtain updated mean (μ_{zt}) and covariance (Σ_{zt}) of latent representation (Zt) of the Kalman filter, decode the latent representation to obtain mean (μₓₜ) and covariance (Σₓₜ) of a reconstruction of the data, and output the reconstruction at a time t.

A system for processing time series data includes and encoder, a Kalman Update block, a locally linear Kalman Filter, an Inference network, a Gated Recurrent Unit, and a decoder. The encoder may be configured to receive an observation (xₜ) and output an uncertainty vector (σ_{wt}) and a latent observation (wₜ). The Kalman Update block may be configured to receive the uncertainty vector and latent observation and output a mean of the latent representation (μ_{zt}) and a covariance of the latent representation (Σ_{zt}). The locally linear Kalman Filter may be configured to receive weights (αₜ), the prior mean of the latent representation, and the prior covariance of the latent representation and output the posterior mean of the latent representation and posterior covariance of the latent representation. The inference network may be configured to receive the latent observation and a deterministic recurrent cell (hₜ), and output a switching variable (sₜ) and weights for the locally linear Kalman Filter. The Gated Recurrent Unit may be configured to receive the switching variable and output the deterministic recurrent cell. The decoder may be configured to receive the latent representation and output a mean of the latent observation (μₓₜ) and a covariance of the latent observation (Σₓₜ).

### BRIEF DESCRIPTION OF THE DRAWINGS

FIG. 1 is a flow diagram of a Switching Recurrent Kalman Network (SRKN).

FIG. 2 is a data flow diagram of the Switching Recurrent Kalman Network of FIG. 1.

FIG. 3 is a graphical representation of trajectories generated by the Switching Recurrent Kalman Network.

FIG. 4 is a graphical representation of image sequences generated by the Switching Recurrent Kalman Network based on the first two time steps.

FIG. 5 is a block diagram of an electronic computing system configured to execute the Switching Recurrent Kalman Network.

FIGS. 6a-6d are graphical representations of trajectories generated by the Switching Recurrent Kalman Network based on an initial observation.

FIG. 11 is a schematic diagram of a control system configured to control a vehicle.

FIG. 12 is a schematic diagram of a control system configured to control a manufacturing machine.

FIG. 13 is a schematic diagram of a control system configured to control a power tool.

FIG. 14 is a schematic diagram of a control system configured to control an automated personal assistant.

FIG. 15 is a schematic diagram of a control system configured to control a monitoring system.

FIG. 16 is a schematic diagram of a control system configured to control a medical imaging system.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The term “substantially” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

The term sensor refers to a device which detects or measures a physical property and records, indicates, or otherwise responds to it. The term sensor include an optical, light, imaging, or photon sensor (e.g., a charge-coupled device (CCD), a CMOS active-pixel sensor (APS), infrared sensor (IR), CMOS sensor), an acoustic, sound, or vibration sensor (e.g., microphone, geophone, hydrophone), an automotive sensor (e.g., wheel speed, parking, radar, oxygen, blind spot, torque, LIDAR), a chemical sensor (e.g., ion-sensitive field effect transistor (ISFET), oxygen, carbon dioxide, chemiresistor, holographic sensor), an electric current, electric potential, magnetic, or radio frequency sensor (e.g., Hall effect, magnetometer, magnetoresistance, Faraday cup, Galvanometer), an environment, weather, moisture, or humidity sensor (e.g., weather radar, actinometer), a flow, or fluid velocity sensor (e.g., mass air flow sensor, anemometer), an ionizing radiation, or subatomic particles sensor (e.g., ionization chamber, Geiger counter, neutron detector), a navigation sensor (e.g., a global positioning system (GPS) sensor, magneto hydrodynamic (MHD) sensor), a position, angle, displacement, distance, speed, or acceleration sensor (e.g., LIDAR, accelerometer, Ultra-wideband radar, piezoelectric sensor), a force, density, or level sensor (e.g., strain gauge, nuclear density gauge), a thermal, heat, or temperature sensor (e.g., Infrared thermometer, pyrometer, thermocouple, thermistor, microwave radiometer), or other device, module, machine, or subsystem whose purpose is to detect or measure a physical property and record, indicate, or otherwise respond to it.

Specifically, a sensor may measure properties of a time series signal and may include spatial or spatiotemporal aspects such as a location in space. The signal may include electromechanical, sound, light, electromagnetic, RF or other time series data. The technology disclosed in this application can be applied to time series imaging with other sensors, e.g., an antenna for wireless electromagnetic waves, microphone for sound, etc.

The term image refers to a representation or artifact that depicts perception of a physical characteristic (e.g., audible sound, visible light, Infrared light, ultrasound, underwater acoustics), such as a photograph or other two-dimensional picture, that resembles a subject (e.g., a physical object, scene, or property) and thus provides a depiction of it. An image may be multi-dimensional in that in may include components of time, space, intensity, concentration, or other characteristic. For example, an image may include a time series image. This technology can also be extended to image 3-D acoustic sources or objects.

Forecasting driving behavior or other sensor measurements is an essential component of autonomous and semi-autonomous driving systems. Often real-world multivariate time series data is hard to model because the underlying dynamics are nonlinear and the observations are noisy. In addition, driving data can often be multimodal in distribution, meaning that there are distinct predictions that are likely, but averaging can hurt model performance. In this disclosure a Switching Recurrent Kalman Network (SRKN) is presented for efficient inference and prediction on nonlinear and multimodal time-series data. The architecture of this network switches among several Kalman filters that model different aspects of the dynamics in a factorized latent state. The architecture, resulting scalable and interpretable deep state-space model was test on toy data sets and real driving data from taxis in Porto, Portugal. In all cases, the model captured the multimodal nature of the dynamics in the data.

Consider one embodiment such as predicting the trajectory of a vehicle which is a key competence of future autonomous driving. Future trajectory prediction refers to the estimation of the future state of some agents, given their past measurements. This ability is critical for autonomous vehicles to plan safe future navigations and avoid possible risks. Forecasting is a challenging task as there is an inherent ambiguity and uncertainty in predicting future trajectories. For example, at a given time instance of a traffic scene, there are several goals that a driver could have, and there are several plausible paths to reach each goal. Those goals are often not observable from the outside, making the future non-deterministic and multimodal at the same time. Averaging the dynamics is typically insufficient and in many cases physically difficult. Consider a scenario in which there is an obstacle in the lane that a car is driving in. To avoid the obstacle, the car can change to the left lane or the right lane. Averaging these two possible maneuvers will lead the car to crash straight into the obstacle. The autonomous agents must be aware of these multiple possibilities to safely navigate through urban areas.

A common approach for modeling time series data is state-space models. State-space models rely on latent states whose transition dynamics determine the system's behavior and are related to the measurements through a noisy observation process. A Kalman filter is often used in a state-space model. It is a preferred solution for inferring linear Gaussian systems. However, real-world time series data are often nonlinear, and the data generation process is typically unknown. Unfortunately, posterior inference in nonlinear non-Gaussian systems is generally intractable. There have been several efforts in the deep learning community to overcome the nonlinearity and system identification issue. Two common approaches are either to use approximations to make nonlinear systems tractable or to introduce stochasticity into recurrent neural networks.

The Recurrent Kalman Network (RKN) is an efficient probabilistic recurrent neural network architecture that employs Kalman updates to infer the system state. In general, RKNs follow the first approach and maps the observation onto a latent feature space where the Kalman update is feasible. To overcome the nonlinearity, RKNs maintain a bank of base linear systems that can be interpolated over time.

This disclosure presents an alternative approach for future trajectory prediction that accounts for multimodality and uncertainty. In particular, by employing a Recurrent Kalman Network with a variational inference technique to introduce a deep learning model that can model multimodal dynamics. This model enjoys the interpretability of a state-space model while scaling well for real-time inference and prediction tasks.

This disclosure will present data to demonstrate the proposed models on a real-world task, which is to model taxi trajectory data. Traffic forecasting is an inspiring problem in autonomous driving because of its nonlinear temporal and spatial dependency. Understanding this traffic behavior is important for monitoring urban traffic and electronic traffic dispatching.

In machine learning, a Bayesian framework is often employed to quantify a degree of uncertainty in an event. In Bayesian modeling, probabilities are adopted to systematically reason about model uncertainty. A prominent example of combining Bayesian modeling and deep learning are variational autoencoders (VAEs). These are unsupervised deep learning models which attempt to find a compressed representation of the observations in some latent space. The VAEs have enjoyed widespread adoption and have been extended to incorporate temporal dependencies.

Time series data are often described by state-space models. State-space models assume that there is an underlying system that governs the observation generation process. This system evolves over time, causing temporal dependencies in the observations. In state-space models, both the observations and the underlying system states are modeled with probability distributions. The notion of the state-space model has its origin back to the 1960s, with the introduction of the Kalman Filter for linear and Gaussian system. Despite its elegant computation and simplicity, the Kalman Filter is limited to linear and Gaussian state-space models. A line of works in the control theory community proposes to address multimodality and nonlinearity problems by maintaining a bank of K linear systems and interpolate between them. However, these methods often require the knowledge of system parameters and are not designed to work with high-dimensional data.

Deep state-space models enjoy tractability, but they are often not expressive enough to capture multimodality. Non-linear deep SSMs have emerged as an alternative, but they lose their tractability and have to resort to approximation techniques. Although all these deep state-space models are successful in modeling complex real-world time series data, they are not explicitly designed to capture multimodality.

Recurrent Kalman Network is a probabilistic recurrent neural network architecture for sequential data that employs Kalman updates to learn a latent state representation of the system. It achieves competitive results on various state estimation tasks while providing reasonable uncertainty estimates and efficiency. In this work, we propose to combine a Recurrent Kalman Network with a switching Kalman Filter to account for multimodal dynamics of time series data.

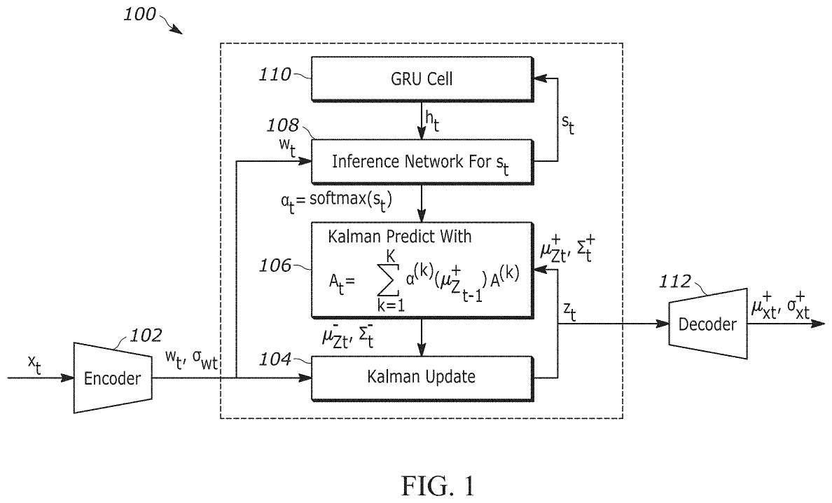

FIG. 1 is a flow diagram of a Switching Recurrent Kalman Network (SRKN) 100. The SRKN includes an encoder 102, an Update Block 104, a Kalman Filter 106, an Inference network 108, a Gated Recurrent Unit Cell 110, and a Decoder 112.

FIG. 1 is also referred to as the architecture of the Switching Recurrent Kalman Network. The encoder maps the observations (xₜ) onto a latent feature space (wₜ). The encoder also produces an uncertainty vector for the mapped latent observations. There is a gated recurrent unit cell that stores information about the switching variable (sₜ) over time. The latent observation is combined with the GRU cell to approximate the posterior distribution for the switching variable. A single sample of this posterior goes to a softmax layer to produce the weighting coefficients for the transition base matrices. The posterior distribution of the latent state from the previous time step is combined with the weighted base matrices to form the predictive distribution for the current latent state. The resulting prediction is then filtered using the latent observation and its uncertainty vector in the Kalman update step. After that, a single sample from the posterior is input to the decoder to parameterize the approximated distribution for the current observation.

A Switching Recurrent Kalman Network (SRKN) is an extension of a Recurrent Kalman Network that accounts for multimodality. The architecture of the model is visualized in FIG. 1. The SRKN employs a latent observation and latent state space. The observations, such as images, are mapped onto a latent observation space where linear dynamics are feasible. The transformation to this latent feature space is given by the SRKN encoder and can be learned end-to-end. In this latent space, exact posterior inference can be done with Kalman Filter.

The Generative Model in the Latent Space. The latent state space Z=R^{2m} is related to the latent observation by a simple linear emission function shown in Equation 1,

wₜ=Hzₜ; H=[Iₘ0_{m×m}], (1)

where m is the dimensionality of the latent observation, Iₘ denotes the identity matrix, and 0_{m×m} represents a m×m matrix filled with zeros. This emission model effectively splits the latent state vector into two parts. The first (upper) part contains information which is included in the observation, and the second (lower) part, the memory, is the information inferred over time, e.g., velocities. Depending on the input dimension (images or real-valued), an uncertainty vector is also output by the decoder.

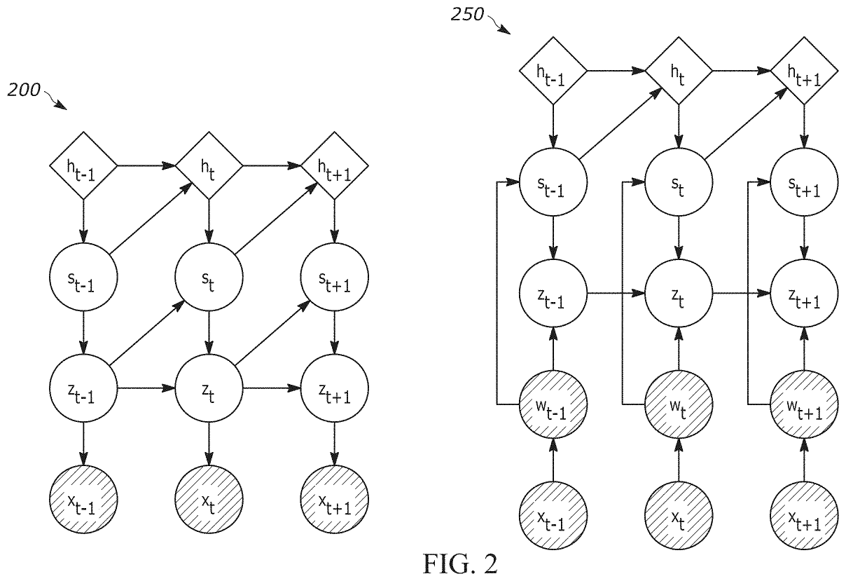

FIG. 2 is a data flow diagram of the Switching Recurrent Kalman Network of FIG. 1. This figure illustrates a generative model 200 and an inference model 250 of the Switching Recurrent Kalman Network.

In the generative model, the switching variable sₜ is conditioned on its distribution up to the current time step and the previous latent state zₜ. The deterministic recurrent cell hₜ stores information about sₜ over time. sₜ determines the weights of the base matrices. The linear model in time step t is a weighted sum of the base systems. The current latent state is related to the previous latent state by a linear model, given the switching variable. The observation xₜ is disentangled from the latent state. In the inference model, the dependency of sₜ on zₜ₋₁ is discarded. In addition, the real observations are mapped onto a latent representation wₜ. wₜ is used to do the inference of sₜ and zₜ. This has the advantage that the inference of zₜ is available in closed-form with the Kalman Filter.

The Generative Model in the Observation Space. The decoder f_{dec} parameterizes the distribution of the reconstructed observation using a single sample of the latent state shown in Equation 2,

p(xₜ|zₜ, sₜ)=N(μₓₜ, Σₓₜ)where [μₓₜ, Σₓₜ]=f_{dec}(zₜ); zₜ·p(zₜ|sₜ, zₜ₋₁). (2)

The Transition Model. The SRKN assumes the system dynamics evolve locally linearly over time. This way, the system state can be inferred online with a Kalman Filter. To obtain a locally linear transition dynamics, the SRKN maintains a bank of transition base matrices A^{(k)}, and the transition matrix at each time step is a weighted sum of these base matrices. The predictive distribution for the latent state at time step t is represented by Equation 3,

$${A}_{t} = {\sum }_{k = 1}^{K} {α}_{t}^{( k )} {A}^{( k )} ; \qquad ( 3 )$$

$${α}_{t} = ( {α}_{t}^{( 1 )} , … , {α}_{t}^{( K )} ) = softmax ( {s}_{t} ) ;$$

$${\sum }_{k = 1}^{K} {α}_{t}^{( k )} = 1 ;$$

$${α}_{t}^{( k )} \geq 0$$

$$p ( {z}_{t} \vert {s}_{t} , {z}_{t - 1} ) = 𝒩 ( {μ}_{{z}_{t}} - , {Σ}_{{z}_{t}} - ) where$$

$${μ}_{{z}_{t}^{-}} = {A}_{t} {μ}_{{z}_{t - 1}^{+}} ;$$

$${Σ}_{{z}_{t}^{-}} = {A}_{t} {Σ}_{{z}_{t - 1}^{+}} {A}_{t}^{T} + L {σ}^{trans} .$$

Here μ_{z-t} and Σ_{z-t} denote the prior mean and the prior covariance of zₜ while μ_{z}_{^{t−1}}⁺ and Σ_{z}_{_{t−1}}⁺ represents the mean and the covariance of the posterior of the previous latent state zₜ₋₁. In addition, αₜ^{(k)} indicates the weight assigned to the k-th linear base matrix. Its value is non-negative and all weights sum to one. The idea of having several transition base matrices is close to the Switching Kalman Filter. The weights assigned to the transition base matrices are given by the switching variable sₜ.

This switching variable is conditioned on its distribution in previous time steps and on the latent state of the previous time step. To this extend, a gated recurrent unit g is adopted to store information about the switching variable over time. A neural network fₜᵣₐₙₛ is used to combine information from the latent state and the switching variable shown in Equation 4,

p(sₜ|s_{<t}, zₜ₋₁)= [symbol] (μₛ_{ₜ}, Σₛ_{ₜ})where[μₛ_{ₜ}, Σₛ_{ₜ}]=fₜᵣₐₙₛ(hₜ, zₜ₋₁); hₜ=g(hₜ₋₁, sₜ₋₁)αₜ=softmax(sₜ); sₜ˜ [symbol] (μₛ_{ₜ}, Σₛ_{ₜ}). (4)

The weighting coefficients for the base matrices are obtained by putting a sample of sₜ through a softmax layer. In summary, the generative model is factorized as shown in Equation 5,

$$p ( {x}_{1 : T} , {z}_{1 : T} , {s}_{1 : T} ) = {{\prod }_{t = 1}}^{T} p ( {x}_{t} \vert {s}_{t} , {z}_{t} ) p ( {z}_{t} \vert {s}_{t} , {z}_{t - 1} ) p ( {s}_{t} \vert {s}_{< t} , {z}_{t - 1} ) . \qquad ( 5 )$$

The Inference Model: This disclosure presents the following factorization of the inference model shown in Equation 6,

$$q ( {s}_{1 : T} , {z}_{1 : T} \vert {x}_{1 : T} ) = {{\prod }_{t = 1}}^{T} q ( {s}_{t} , {z}_{t - 1} , {x}_{t} ) q ( {s}_{t} \vert {s}_{< t} , {x}_{t - 1} ) \qquad ( 6 )$$

$$q ( {s}_{t} \vert {s}_{< t} , {x}_{t} ) = 𝒩 ( {μ}_{{s}_{t}} , {Σ}_{{s}_{t}} ) where$$

$$[ {μ}_{{s}_{t}} , {Σ}_{{s}_{t}} ] = {f}_{inf} ( {s}_{< t} , {x}_{t} )$$

$$p ( {z}_{t} \vert {s}_{t} , {z}_{t - 1} , {x}_{t} ) = 𝒩 ( {μ}_{{z}_{t}^{+}} , {Σ}_{{z}_{t}^{+}} ) where$$

$$[ {μ}_{{z}_{t}^{+}} , {Σ}_{{z}_{t}^{+}} ] = Kalman\_Update ( {μ}_{{z}_{t}^{-}} , {Σ}_{{z}_{t}^{-}} ) .$$

The inference for zₜ is given by a factorized Kalman update introduced by the RKN. Here, the condition of sₜ on zₜ₋₁ is discarded, see FIG. 2. Empirical experiments illustrate that removing this condition in the inference model resolves the mode averaging problem when training the model.

The inference of the switching variable is done with the amortized variational inference technique, where the inference networks and the generative networks are trained together. These networks have the task of parametrizing the probability distributions of the switching variable and the observations. Also, the inference of the latent system state follows the elegant computational structure of the RKN, in which the filtering process can be simplified to scalar operations.

The Evidence Lower Bound: This model belongs to the class of variational approach. The variational inference technique formulates a tractable lower bound for the complex distribution of interest and thus transforms the approximation of some intractable posterior into an optimization problem. This is obtained by finding an approximated posterior distribution that minimizes the KL-divergence of it to the real posterior. Minimizing the KL divergence is equivalent to maximizing the following evidence lower bound (ELBO) shown in Equation 7,

$${ℒ}_{ELBO} = {\sum }_{t = 1}^{T} {𝔼}_{q ( {z}_{t} \vert {s}_{t} , {z}_{t - 1} , {f}_{w} ( {x}_{t} ) ) q ( {s}_{t} \vert {s}_{< t} , {f}_{w} ( {x}_{t} ) )} [ log p ( {x}_{t} \vert {s}_{t} , {z}_{t} ) ] - {𝔼}_{q ( {s}_{t} \vert {s}_{< t} , {z}_{t - 1} , {f}_{w} ( {x}_{t - 1} ) )} {𝔼}_{q ( {z}_{t - 1} \vert {s}_{t - 1} , {z}_{t - 2} , {f}_{w} ( {x}_{t - 1} ) )} [ KL ( q ( {z}_{t} \vert {s}_{t} , {z}_{t - 1} , {f}_{w} ( {x}_{t} ) ‖ p ( {z}_{t} \vert {s}_{t} , {z}_{t - 1} ) ) ] ] - {𝔼}_{q ( {s}_{1} \vert {f}_{w} ( {x}_{1} ) )} [ … {𝔼}_{q ( {s}_{t} \vert {s}_{< t} , {z}_{t - 1} , {f}_{w} ( {x}_{t} ) )} [ {𝔼}_{q ( {z}_{t - 1} \vert {s}_{t - 1} , {z}_{t - 2} , {f}_{w} ( {x}_{t - 1} ) )} [ KL ( q ( {s}_{t} \vert {s}_{< t} , {z}_{t - 1} , {f}_{w} ( {x}_{t} ) ) ‖ p ( {s}_{t} \vert {s}_{< t} , {z}_{t - 1} ) ) ] ] ] . \qquad ( 7 )$$

Here, f_{w} denotes the function that maps the real observation xₜ to the latent observation wₜ. This disclosure introduces a scaling factor for each component of the ELBO. These scaling factors are motivated by the β-VAE and govern the trade-off between the reconstruction term and the regularization term. Depending on the problems at hand, tuning these scaling factors might be beneficial to the overall training performance. Besides, we add a prediction loss term to guide the model training process. This prediction loss term is the weighted sum of K observation probabilities. Each probability p^{(k)}(xₜ|sₜ, zₜ₋₁) refers to the observation probability when the transition of the latent state zₜ follows the linear base system A^{(k)}. Intuitively, the prediction loss term corresponds to the log probability of a mixture model with K components. The prediction loss term enforces the model to assign higher weight on the base systems that are more likely to generate the subsequent observation. The resulting objective function is as shown in Equation 8,

$${ℒ}_{Objective} = {ℒ}_{β\_ ELBO} + {β}_{pred} {ℒ}_{Pred} , \qquad ( 8 )$$

$$where$$

$${ℒ}_{pred} = {\sum }_{t = 1}^{T} log {\sum }_{k = 1}^{K} {α}_{t}^{( k )} {p}^{( k )} ( {x}_{t} \vert {s}_{t} , {z}_{t - 1} ) \qquad ( 9 )$$

$$where {p}^{( k )} ( {x}_{t} \vert {s}_{t} , {z}_{t - 1} ) = {𝔼}_{{p}^{( k )} ( {z}_{t} \vert {s}_{t} , {z}_{t - 1} )} [ p ( {x}_{t} \vert {s}_{t} , {z}_{t} ) {p}^{( k )} ( {z}_{t} \vert {s}_{t} , {z}_{t - 1} ) ]$$

$${p}^{( k )} ( {z}_{ℓ} \vert {s}_{t} , {z}_{t - 1} ) = 𝒩 ( {z}_{t} ; {A}^{( k )} {z}_{t - 1} , {A}^{( k )} {{Σ}_{{z}_{t - 1}} ( {A}^{( k )} )}^{T} ) . \qquad ( 10 )$$

L_{β_ELBO} refers to the ELBO where the reconstruction loss term, the KL-divergence for zₜ and the KL-divergence for sₜ have a scaling factor β_{rec}, β_{z} and βₛ, respectively.

The SRKN was evaluated with several data sets. First, consider a simulated 2-d time series data set whose dynamics have four modes and a synthetic image data set of car motions that follow an underlying structure. Then apply the SRKN to a real-world taxi data set. The results were then compared against several methods for modelling time-series data, including the RKN, VRNN-GMM, VDM, and DMM-IAF.

Evaluation metrics: Four metrics to evaluate the predictions quantitatively were selected. They included i) one-step prediction loss log p(xₜ|x_{<t}), ii) multi-step prediction loss log p(x_{t:t+τ}|x_{<t}), iii) reconstruction log likelihood log p(xₜ|x_{≤t}) and iv) Wasserstein distance. A real-valued observation is modeled with a multivariate Gaussian distribution with diagonal covariance. The negative Gaussian reconstruction log-likelihood for a sequence in this case is shown by Equation 11,

$$ℒ ( {x}_{1 : T} ) = \frac{1}{T} {\sum }_{t = 1}^{T} - log 𝒩 ( {x}_{t} \vert {μ}_{{x}_{t}}^{+} , {σ}_{{x}_{t}}^{+} ) . \qquad ( 11 )$$

The negative high-dimensional data are modeled with a Bernoulli distribution. The reconstruction log-likelihood is computed as shown in Equation 12,

$$ℒ ( {x}_{1 : T} ) = - \frac{1}{T} {\sum }_{t = 1}^{T} {\sum }_{d = 0}^{D} {x}_{t}^{( d )} log ( {μ}_{{x}_{t}}^{( d ) +} ) + ( 1 - {μ}_{{x}_{t}}^{( d ) +} ) log ( 1 - {μ}_{{x}_{t}}^{( d ) +} ) . \qquad ( 12 )$$

The one-step prediction loss term demonstrates the prediction power of the model for the next time step, given the observations up to the current time step is shown by Equation 13,

$${ℒ}_{one \_ step} ( {x}_{1 : T} ) = {\sum }_{t = 1}^{T - 1} - log p ( {x}_{t \div 1} \vert {x}_{1 : t} ) . \qquad ( 13 )$$

To compute the multi-step prediction loss, generate n=100 predictions for the rest of the sequence, given observations up to time step τ as shown in Equation 14,

$${ℒ}_{multi \_ steps} ( {x}_{1 : T} ) = \frac{1}{n} {\sum }_{i = 1}^{n} {\sum }_{t = τ}^{T - 1} - log {p}_{( i )} ( {x}_{t + 1} \vert {x}_{1 : τ} ) . \qquad ( 14 )$$

The Wasserstein distance accounts for both diversity and accuracy of prediction. To approximate the Wasserstein distance, select n samples from a test set that has similar initial trajectories. The model is expected to generate sample predictions that match all ground truth continuations in the test set, given the initial trajectories.

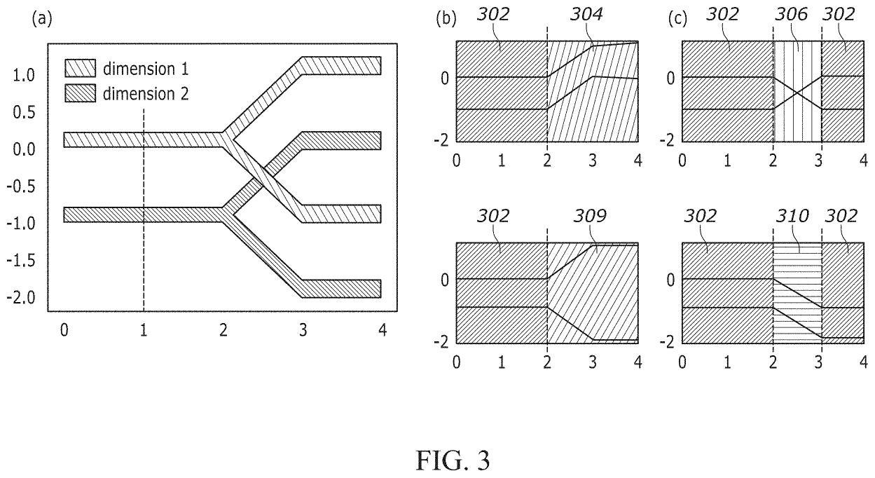

FIG. 3 is a graphical representation of trajectories generated by the Switching Recurrent Kalman Network. Figure (a) represents trajectories generated by the SRKN. Figures (b-e) illustrate different transition modes that the model assigns to each possible continuation of the trajectory. Each element 302, 304, 306, 308, 310 corresponds to one transition dynamic mode. Each time step is grayscale-coded (302, 304, 306, 308, 310) with the mode that the model assigns the highest weight to.

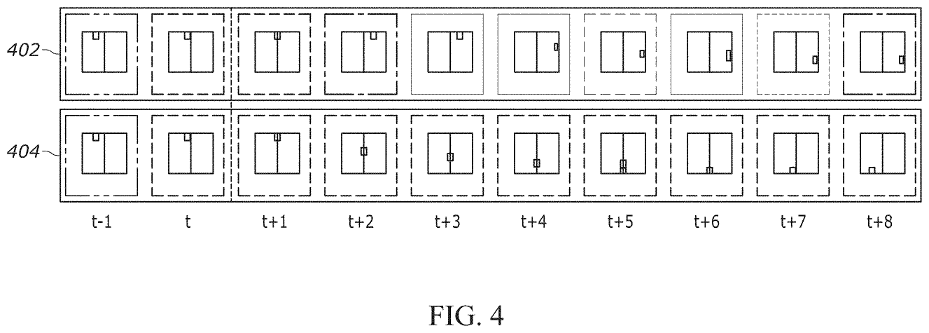

FIG. 4 is a graphical representation of image sequences 400 generated by the Switching Recurrent Kalman Network based on the first two time steps (t−1 and t). Two image sequences (402 and 404) were generated by the SRKN given the two first time steps (t−1 and t). Each grayscale corresponds to one transition dynamic mode. Each image is grayscale-coded with the mode that the model assigned the highest weight to. The two rectangles are not present in the dataset but only serve for visualization. Here, the model can determine the two potential trajectories that the car can follow when approaching the crossroad.

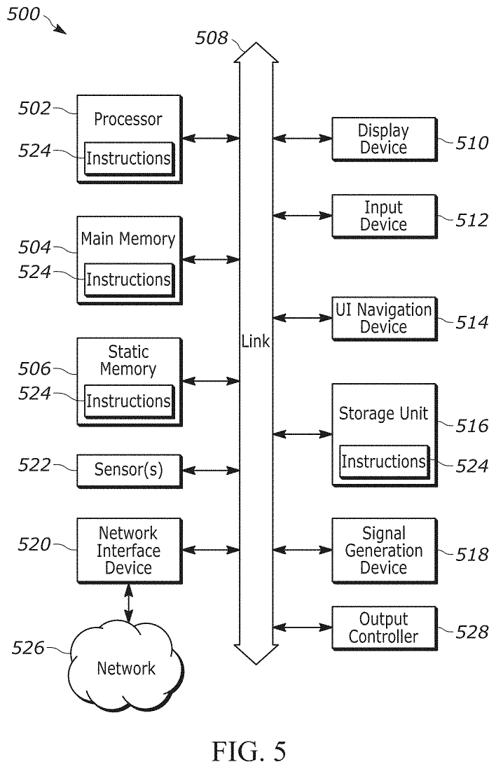

FIG. 5 is a block diagram of an electronic computing system configured to execute the Switching Recurrent Kalman Network. This electronic computing system may also include a telecommunication system, Machine Architecture, and Machine-Readable Medium. FIG. 5 is a block diagram of an electronic computing system suitable for implementing the systems or for executing the methods disclosed herein. The machine of FIG. 5 is shown as a standalone device, which is suitable for implementation of the concepts above. For the server aspects described above a plurality of such machines operating in a data center, part of a cloud architecture, and so forth can be used. In server aspects, not all of the illustrated functions and devices are utilized. For example, while a system, device, etc. that a user uses to interact with a server and/or the cloud architectures may have a screen, a touch screen input, etc., servers often do not have screens, touch screens, cameras and so forth and typically interact with users through connected systems that have appropriate input and output aspects. Therefore, the architecture below should be taken as encompassing multiple types of devices and machines and various aspects may or may not exist in any particular device or machine depending on its form factor and purpose (for example, servers rarely have cameras, while wearables rarely comprise magnetic disks). However, the example explanation of FIG. 5 is suitable to allow those of skill in the art to determine how to implement the embodiments previously described with an appropriate combination of hardware and software, with appropriate modification to the illustrated embodiment to the particular device, machine, etc. used.

While only a single machine is illustrated, the term “machine” shall also be taken to include any collection of machines that individually or jointly execute a set (or multiple sets) of instructions to perform any one or more of the methodologies discussed herein.

The example of the machine 500 includes at least one processor 502 (e.g., controller, microcontroller, a central processing unit (CPU), a graphics processing unit (GPU), tensor processing unit (TPU), advanced processing unit (APU), or combinations thereof), one or more memories such as a main memory 504 a static memory 506, or other types of memory, which communicate with each other via link 508. Link 508 may be a bus or other type of connection channel. The machine 500 may include further optional aspects such as a graphics display unit 510 comprising any type of display. The machine 500 may also include other optional aspects such as an alphanumeric input device 512 (e.g., a keyboard, touch screen, and so forth), a user interface (UI) navigation device 514 (e.g., a mouse, trackball, touch device, and so forth), a storage unit 516 (e.g., disk drive or other storage device(s)), a signal generation device 518 (e.g., a speaker), sensor(s) 521 (e.g., global positioning sensor, accelerometer(s), microphone(s), camera(s), and so forth), output controller 528 (e.g., wired or wireless connection to connect and/or communicate with one or more other devices such as a universal serial bus (USB), near field communication (NFC), infrared (IR), serial/parallel bus, etc.), and a network interface device 520 (e.g., wired and/or wireless) to connect to and/or communicate over one or more networks 526.

The various memories (i.e., 504, 506, and/or memory of the processor(s) 502) and/or storage unit 516 may store one or more sets of instructions and data structures (e.g., software) 524 embodying or utilized by any one or more of the methodologies or functions described herein. These instructions, when executed by processor(s) 502 cause various operations to implement the disclosed embodiments.

Toy Experiments

2-d Synthetic Data Set. Start with a simple two-dimensional data set to verify the ability of the proposed model in capturing multimodality. Each sequence consists of five time-steps. The data sequences have a constant value in the first three steps. At time step 4, each dimension of the data point can switch to two possible modes, causing the data to have four modes in total. FIG. 3 is a visualization of the results. The model can successfully capture the switching point at the fourth time step.

Synthetic Car Trajectories Images Data Set. Next, evaluate the SRKN on a simple synthetic car trajectories image dataset. The observations here are sequences of images of 24×24 pixels. The black square represents a car whose trajectory follows an underlying pattern containing two rectangles next to each other. Each image illustrates the position of the car at a time. The car never goes in the opposite direction at any given time step. The qualitative results are demonstrated in FIG. 4. Each image is coded with the dominant mode that the model predicts. The black square seems blurred in the later time steps, which is presumably caused by the transition noise incorporated in the model. It is noteworthy that although the models were trained on sequences of only length 6, they can give good predictions for longer sequences. In other words, the models can learn and generalize the underlying dynamics of the data. Hence, a potential application of the SRKN is to model real-world trajectories image data in autonomous driving. Note that the two rectangles are not included in the dataset but only serve evaluation purposes.

The quantitative results for the toy experiments are given in Table 4. This model achieved competitive results as the VDM on the four mode data set, while on the pendulum image data set, it achieves the best one-step and multi-step prediction performance.

TABLE 1
Quantitative results on four modes and car trajectories datasets. In the
four modes data set, the SRKN and the VDM have the smallest Wasserstein
distance. This indicates their similar performance in prediction and capturing
multimodality. Compared to the RKN, the SRKN achieves a smaller one-step
and multi-step prediction loss. Among all baselines, only the VDM has a
better one-step and multi-step prediction loss than the SRKN. In the car
trajectories data set, the SRKN outperforms all the baseline models in
terms of prediction loss and Wasserstein distance. The reconstruction loss
of the RKN in this image dataset is slightly better than the SRKN.

| Four modes data set | | | | | Car trajectories data set | | | |
|---|---|---|---|---|---|---|---|---|
| | 1-step | Multi-step | w-dist | LL | 1-step | Multi-step | w-dist | LL |
| VDM | −4.83 | 2.11 | 0.10 | −4.90 | 7.04 | 7.45 | 6.44 | 6.23 |
| RKN | −3.91 | 3.41 | 0.22 | −4.83 | 4.33 | 5.33 | 7.11 | 2.63 |
| VRNN | −3.96 | 2.59 | 0.13 | −5.06 | 5.14 | 8.14 | 6.21 | 4.93 |
| DMM | −2.94 | 4.00 | 0.72 | −5.21 | 7.86 | 8.04 | 6.44 | 6.87 |
| SRKN | −4.12 | 2.37 | 0.10 | −5.07 | 4.33 | 5.10 | 4.40 | 2.74 |

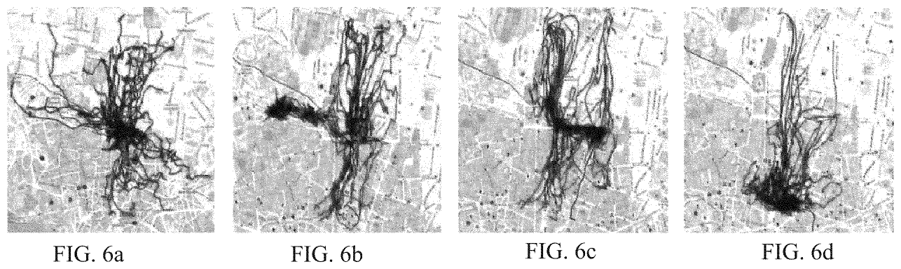

FIG. 6a-6d are graphical representations of trajectories generated by the Switching Recurrent Kalman Network based on different initial observation. 50 generated trajectories (thin line) given the initial observations (bold line). The model can generate trajectories that follow the general evolving structure of the underlying map.

Real World Taxi Data Set: To validate the effectiveness of the proposed model, an experiment on a Porto taxi data set was performed. The original data set consists of 1.7 million records, coming from 442 taxis running in Porto, Portugal. For evaluation, the preprocessing pipeline was reused. Only the trajectories in the city area were selected and only the first 30 time steps were extracted. The resulting dataset is split into the training set of size 86,386, the validation set of size 200, and the test set of size 10,000. FIG. 6 demonstrates the qualitative forecasting results. The task is to predict the next 20 time steps given the first 10 time steps. The model can capture the multimodal dynamics and give predictions that follow the underlying evolution structure of the map. Compared to the state-of-the-art model for multimodality such as VDM, SRKN cannot achieve such good prediction results. This could be because while SRKN employs a linear state transition model, the state transition in the VDM is nonlinear and is represented by a powerful deep neural network.

TABLE 2
Quantitative results on taxi data sets. The VDM
outperforms all baseline models in terms of
prediction loss and Wasserstein distance. In
comparison to the RKN, the SRKN exhibits a
much smaller Wasserstein distance and multi-step
prediction loss. This shows an improvment of
the SRKN compared to the RKN in the long-term
and multimodal predictive power.
Taxi data set

| | 1-step | Multi-step | w-dist | LL | # parameters |
|---|---|---|---|---|---|
| VDN | −3.68 | 2.88 | 0.59 | −4.33 | 22056 |
| RKN | −2.9 | 4.2 | 2.07 | −4.25 | 23118 |
| VRNN | −2.77 | 5.51 | 2.43 | −4.09 | 22352 |
| DMM | −2.45 | 3.29 | 0.7 | −4.35 | 22248 |
| SRKN | −2.35 | 3.16 | 0.75 | −4.34 | 33742 |

A switching recurrent Kalman network for multimodal modeling of time series data is presented above. The model consists of a recurrent neural network for the switching variable and a locally linear state transition model. It operates on a latent observation space where a linear transition model is feasible. This enforces the state-space model assumption and enjoys an explicit notion of the system state. The inference of the system state follows the efficient computation structure of the RKN, while the inference of the switching variable is performed using an amortized variational inference method. The model illustrates the ability to capture multimodality on the real-world Porto taxi trajectories dataset. Besides, our model enjoys the interpretability of a state-space model with switching regimes and outperforms the baseline models on high-dimensional car trajectory data. The ability of this model to incorporate uncertainty and multimodality in future predictions promises a wide range of applications in autonomous driving, such as the trajectory prediction of pedestrians and nearby vehicles.

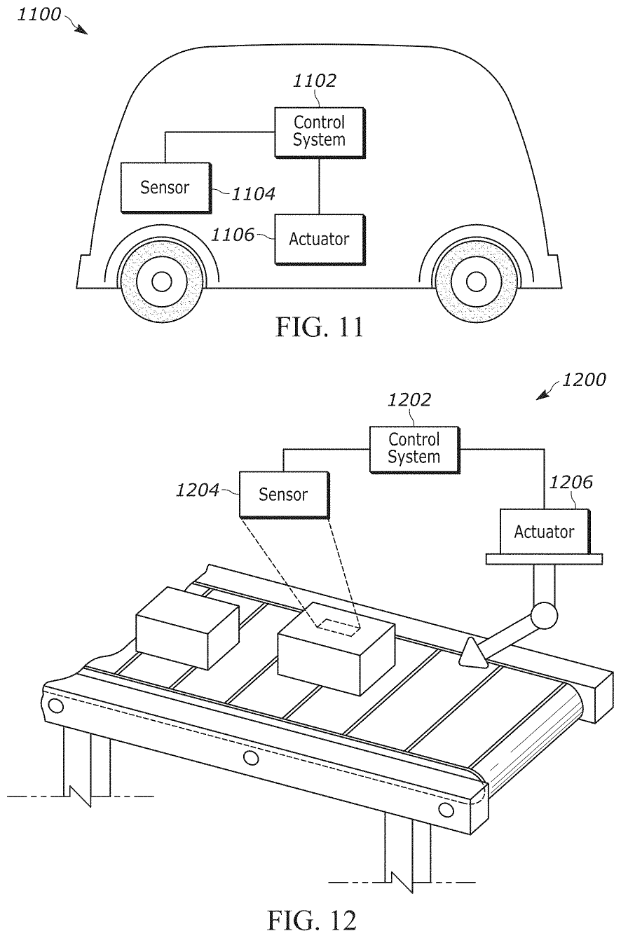

This technology can be applied to other serial data are provided in FIGS. 11-16. FIGS. 11-16 illustrate exemplary embodiments however the concepts of this disclosure may be applied to additional embodiments. Some exemplary embodiments include: Industrial applications in which the modalities may include video, weight, IR, 3D camera, and sound; power tool or appliance applications in which the modalities may include torque, pressure, temperature, distance, or sound; medical applications in which the modalities may include ultrasound, video, CAT scan, Mill, or sound; robotic applications in which the modalities may include video, ultrasound, LIDAR, IR, or Sound; and security applications in which the modalities may include video, sound, IR, or LIDAR. The modalities may have diverse datasets for example, a video dataset may include an image, a LIDAR dataset may include a point cloud, and a microphone dataset may include a time series.

The technology disclosed here can be used by operating on time series data, which may be obtained by receiving sensor signals, e.g GPS signals of vehicles, or emissions of engine. Accurate forecasting models of typical driving behavior, of typical pollution levels over time, or of the dynamics of an engine can help both lawmakers and/or automotive engineers to develop solutions for cleaner mobility. Other exemplary applications include:

Video classification: Use existing methods to extract frame-based features from the video (e.g. object tracking). Based on the framed based-features learn forecasting model. On unseen videos, after watching the first few frames (and extracting the features) the VDM can predict plausible continuations of the features. These forecasts can be used for video classification. These forecasted features are fed into a classifier with different possible effects based on the use-case (e.g., predict traffic, predict accident about to happen (and if accident likely, dispatch emergency support), predict scene violence/nonviolence (and if violence likely, turn off video)).

Autonomous Driving: External model: Use sensor measurements (e.g. video, LIDAR, communication with other smart-vehicles or smart-city devices) to extract features about other traffic participants and surrounding objects. Features could be 3D-world coordinates, coordinates relative to ego-vehicle, of surrounding objects and traffic participants). Also, this can train VDM on such extracted features. A trained model can then be used in a vehicle: When new sensor measurements are recorded, features need to be extracted and these can then be forecasted by VDM into the future. These forecasts can trigger different behaviors of the ECU (e.g., slowing down, emergency break, etc.).

A Driver model can use sensor measurements (e.g. video, steering, breaking, communication with driver's smart-watch) to extract features about the driver. Features include steering, acceleration, eye-movement, and heart rate. The VDM can be trained on such extracted features. A trained model can then be used in a vehicle: When new sensor measurements are recorded, features need to be extracted and these can then be forecasted by VDM into the future. These forecasts can trigger different behaviors of the ECU (e.g., slowing down, emergency break, etc.).

An Engine model can use sensor measurements (e.g. e.g. from ECU) to extract features about the engine dynamics. Features include any of the ECU parameters and derived quantities. The FDM can be trained on such extracted features. A trained model can then be used in a vehicle, and when new sensor measurements are recorded such that features that need to be extracted can then be forecasted by VDM in the future. These forecasts can trigger different behaviors of the ECU (e.g., slowing down, emergency break, etc.).

Battery state of health (SOH) or battery state of charge (SOC) are used to track route features and features of driver behavior (e.g. speed and elevation of the route) and the VDM can be trained on such features.

Internet of things (TOT) (e.g., smart-home, smart-manufacturing). A system can collect and track sensor measurements and use them and derived quantities as features. The system can have defined critical thresholds for some of those features (e.g. min oxygen levels, max temperature, etc.). Then when new measurements come in the system can use VDM to create a forecast. If a critical threshold is likely to be violated within specified time horizon, the system can take an emergency action (e.g. stop production line, open valve to let in e.g. fresh oxygen, open window, lock emergency doors).

Digital Twins can be used to prototype a new engineering device (e.g. power tool, home appliance, new engine design, etc.) and collect data from internal sensors of the device and/or external sensors e.g. video, LIDAR) under normal usage. These measurements and/or derived quantities as features can be used to train the VDM on these features. Forecasted behaviors can be used to find anomalies in device behavior (e.g. energy consumption too high, device breaks too soon, overheats etc.) Should device operation be expected to result in undesired behavior, the device can be shut off automatically, or it's settings could be switched into safe mode.

Resource allocation in which a system measures demand in different nodes of a network (e.g. computer network, telecommunications network, wireless network). The system then in conjunction with other measurements at the nodes (e.g. temperature, time of day) and/or derived quantities as features could be used to record and train a VDM model. Then on new data, the system can use the VDM to predict demand. For example, if demand is predicted to surpass a critical threshold at a certain node, do additional resource allocation. Apart from resource allocation, load prediction is also needed for congestion control and routing algorithms. At each access point of a wireless network, resources such as spectrum and transmission power are highly limited and are allocated on-demand. Briefly, based on the user's application type (e.g., an IoT user or a mobile user), quality of service requirement (e.g., data rate, reliability, latency), communication channel condition (signal to inference and noise ratio) and etc., the resource allocator assigns it with the corresponding transmission time slot, frequency, power and also the transmission format. A good load prediction algorithm is helpful for a timely allocation of resources, e.g., reserving spectrum if latency critical traffic is foreseen. To serve the ever increasing number of users under more stringent quality of service requirements, load prediction and resource allocation become more demanding in 5G and beyond.

FIG. 11 is a schematic diagram of control system 1102 configured to control a vehicle, which may be an at least partially autonomous vehicle or an at least partially autonomous robot. The vehicle includes a sensor 1104 and an actuator 1106. The sensor 1104 may include one or more wave energy based sensor (e.g., a Charge Coupled Device CCD, or video), radar, LiDAR, microphone array, ultrasonic, infrared, thermal imaging, acoustic imaging or other technologies (e.g., positioning sensors such as GPS). One or more of the one or more specific sensors may be integrated into the vehicle. Alternatively or in addition to one or more specific sensors identified above, the control module 1102 may include a software module configured to, upon execution, determine a state of actuator 1104.

In embodiments in which the vehicle is an at least a partially autonomous vehicle, actuator 1106 may be embodied in a brake system, a propulsion system, an engine, a drivetrain, or a steering system of the vehicle. Actuator control commands may be determined such that actuator 1106 is controlled such that the vehicle avoids collisions with detected objects. Detected objects may also be classified according to what the classifier deems them most likely to be, such as pedestrians or trees. The actuator control commands may be determined depending on the classification. For example, control system 1102 may segment an image (e.g., optical, acoustic, thermal) or other input from sensor 1104 into one or more background classes and one or more object classes (e.g. pedestrians, bicycles, vehicles, trees, traffic signs, traffic lights, road debris, or construction barrels/cones, etc.), and send control commands to actuator 1106, in this case embodied in a brake system or propulsion system, to avoid collision with objects. In another example, control system 1102 may segment an image into one or more background classes and one or more marker classes (e.g., lane markings, guard rails, edge of a roadway, vehicle tracks, etc.), and send control commands to actuator 1106, here embodied in a steering system, to cause the vehicle to avoid crossing markers and remain in a lane. In a scenario where an adversarial attack may occur, the system described above may be further trained to better detect objects or identify a change in lighting conditions or an angle for a sensor or camera on the vehicle.

In other embodiments where vehicle 1100 is an at least partially autonomous robot, vehicle 1100 may be a mobile robot that is configured to carry out one or more functions, such as flying, swimming, diving and stepping. The mobile robot may be an at least partially autonomous lawn mower or an at least partially autonomous cleaning robot. In such embodiments, the actuator control command 1106 may be determined such that a propulsion unit, steering unit and/or brake unit of the mobile robot may be controlled such that the mobile robot may avoid collisions with identified objects.

In another embodiment, vehicle 1100 is an at least partially autonomous robot in the form of a gardening robot. In such embodiment, vehicle 1100 may use an optical sensor as sensor 1104 to determine a state of plants in an environment proximate vehicle 1100. Actuator 1106 may be a nozzle configured to spray chemicals. Depending on an identified species and/or an identified state of the plants, actuator control command 1102 may be determined to cause actuator 1106 to spray the plants with a suitable quantity of suitable chemicals.

Vehicle 1100 may be an at least partially autonomous robot in the form of a domestic appliance. Non-limiting examples of domestic appliances include a washing machine, a stove, an oven, a microwave, or a dishwasher. In such a vehicle 1100, sensor 1104 may be an optical or acoustic sensor configured to detect a state of an object which is to undergo processing by the household appliance. For example, in the case of the domestic appliance being a washing machine, sensor 1104 may detect a state of the laundry inside the washing machine. Actuator control command may be determined based on the detected state of the laundry.

In this embodiment, the control system 1102 would receive data or an image (optical or acosutic) from sensor 1104. The control system 1102 may use the method described in FIG. 1 to formulate a prediction of the image received from sensor 1104. Based on this prediction, signals may be sent to actuator 1106, for example, to brake or turn to avoid collisions with pedestrians or trees, to steer to remain between detected lane markings, or any of the actions performed by the actuator 1106 as described above. Signals may also be sent to sensor 1104 based on this classification, for example, to focus or move a camera lens.

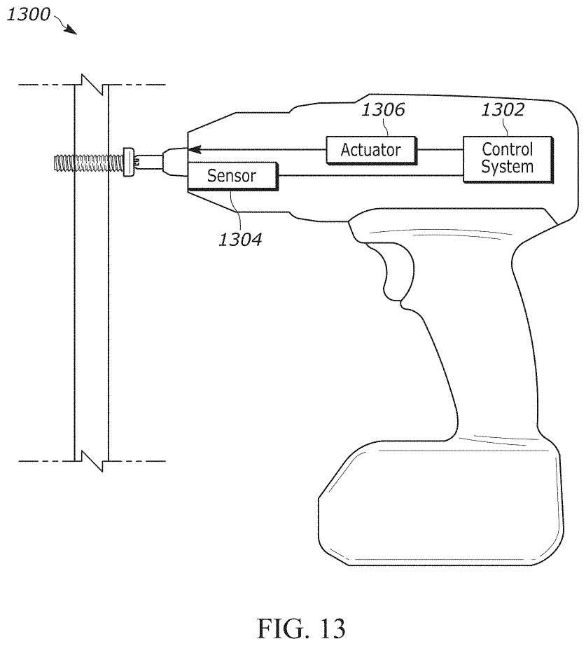

FIG. 12 depicts a schematic diagram of control system 1202 configured to control system 1200 (e.g., manufacturing machine), such as a punch cutter, a cutter or a gun drill, of manufacturing system 102, such as part of a production line. Control system 1202 may be configured to control actuator 14, which is configured to control system 100 (e.g., manufacturing machine).

Sensor 1204 of system 1200 (e.g., manufacturing machine) may be an wave energy sensor such as an optical or acoustic sensor or sensor array configured to capture one or more properties of a manufactured product. Control system 1202 may be configured to determine a state of a manufactured product from one or more of the captured properties. Actuator 1206 may be configured to control system 1202 (e.g., manufacturing machine) depending on the determined state of manufactured product 104 for a subsequent manufacturing step of the manufactured product. The actuator 1206 may be configured to control functions of FIG. 11 (e.g., manufacturing machine) on subsequent manufactured products of the system (e.g., manufacturing machine) depending on the determined state of the previous manufactured product.

In this embodiment, the control system 1202 would receive data or an image (e.g., optical or acoustic) and annotation information from sensor 1204. The control system 1202 may use the method described in FIG. 1 to formulate a prediction of the image received from sensor 1104. Based on this prediction, signals may be sent to actuator 1206. For example, if control system 1202 detects anomalies in a product, actuator 1206 may mark or remove anomalous or defective products from the line. In another example, if control system 1202 detects the presence of barcodes or other objects to be placed on the product, actuator 1106 may apply these objects or remove them. Signals may also be sent to sensor 1204 based on this classification, for example, to focus or move a camera lens.

FIG. 13 depicts a schematic diagram of control system 1302 configured to control power tool 1300, such as a power drill or driver, that has an at least partially autonomous mode. Control system 1302 may be configured to control actuator 1306, which is configured to control power tool 1300.

Sensor 1304 of power tool 1300 may be a wave energy sensor such as an optical or acoustic sensor configured to capture one or more properties of a work surface and/or fastener being driven into the work surface. Control system 1302 may be configured to determine a state of work surface and/or fastener relative to the work surface from one or more of the captured properties.

In this embodiment, the control system 1302 would receive image (e.g., optical or acoustic) and annotation information from sensor 1304. The control system 1302 may use the method described in FIG. 1 to formulate a prediction of the image received from sensor 1304. Based on this prediction, signals may be sent to actuator 1306, for example to the pressure or speed of the tool, or any of the actions performed by the actuator 1306 as described in the above sections. Signals may also be sent to sensor 1304 based on this classification, for example, to focus or move a camera lens. In another example, the image may be a time series image of signals from the power tool 1300 such as pressure, torque, revolutions per minute, temperature, current, etc. in which the power tool is a hammer drill, drill, hammer (rotary or demolition), impact driver, reciprocating saw, oscillating multi-tool, and the power tool is either cordless or corded.

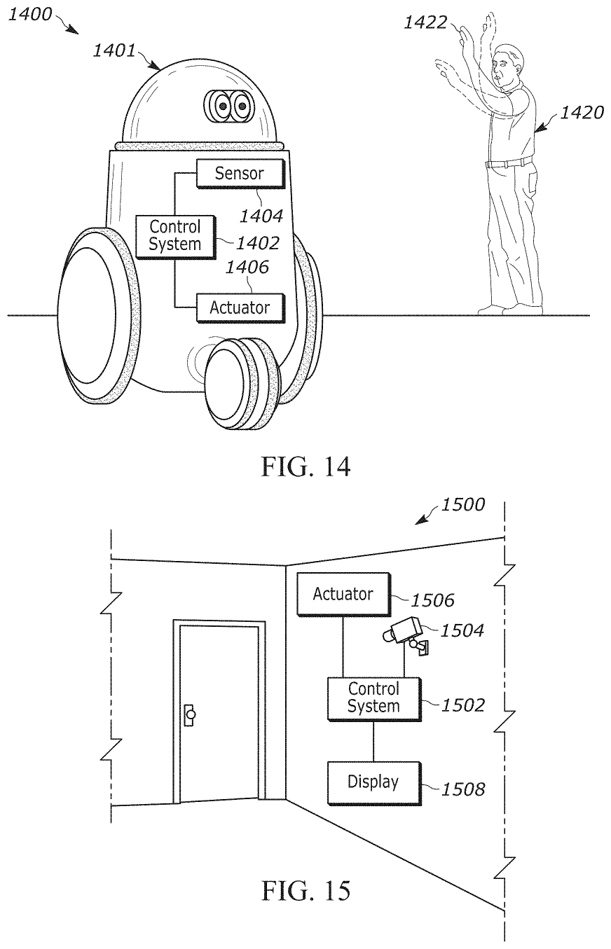

FIG. 14 depicts a schematic diagram of control system 1402 configured to control automated personal assistant 1401. Control system 1402 may be configured to control actuator 1406, which is configured to control automated personal assistant 1401. Automated personal assistant 1401 may be configured to control a domestic appliance, such as a washing machine, a stove, an oven, a microwave or a dishwasher.

In this embodiment, the control system 1402 would receive image (e.g., optical or acoustic) and annotation information from sensor 1404. The control system 1402 may use the method described in FIG. 1 to formulate a prediction of the image received from sensor 1404. Based on this prediction, signals may be sent to actuator 1406, for example, to control moving parts of automated personal assistant 1401 to interact with domestic appliances, or any of the actions performed by the actuator 1406 as described in the above sections. Signals may also be sent to sensor 1404 based on this classification, for example, to focus or move a camera lens.

FIG. 15 depicts a schematic diagram of control system 1502 configured to control monitoring system 1500. Monitoring system 1500 may be configured to physically control access through door 252. Sensor 1504 may be configured to detect a scene that is relevant in deciding whether access is granted. Sensor 1504 may be an optical or acoustic sensor or sensor array configured to generate and transmit image and/or video data. Such data may be used by control system 1502 to detect a person's face.

Monitoring system 1500 may also be a surveillance system. In such an embodiment, sensor 1504 may be a wave energy sensor such as an optical sensor, infrared sensor, acoustic sensor configured to detect a scene that is under surveillance and control system 1502 is configured to control display 1508. Control system 1502 is configured to determine a classification of a scene, e.g. whether the scene detected by sensor 1504 is suspicious. A perturbation object may be utilized for detecting certain types of objects to allow the system to identify such objects in non-optimal conditions (e.g., night, fog, rainy, interfering background noise etc.). Control system 1502 is configured to transmit an actuator control command to display 1508 in response to the classification. Display 1508 may be configured to adjust the displayed content in response to the actuator control command. For instance, display 1508 may highlight an object that is deemed suspicious by controller 1502.

In this embodiment, the control system 1502 would receive image (optical or acoustic) and annotation information from sensor 1504. The control system 1502 may use the method described in FIG. 1 to formulate a prediction of the image received from sensor 1504. Based on this prediction, signals may be sent to actuator 1506, for example, to lock or unlock doors or other entryways, to activate an alarm or other signal, or any of the actions performed by the actuator 1506 as described in the above sections. Signals may also be sent to sensor 1504 based on this classification, for example, to focus or move a camera lens.

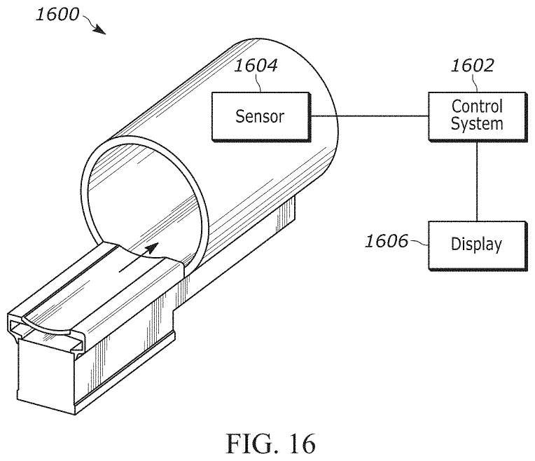

FIG. 16 depicts a schematic diagram of control system 1602 configured to control imaging system 1600, for example an Mill apparatus, x-ray imaging apparatus or ultrasonic apparatus. Sensor 1604 may, for example, be an imaging sensor or acoustic sensor array. Control system 1602 may be configured to determine a classification of all or part of the sensed image. Control system 1602 may be configured to determine or select an actuator control command in response to the classification obtained by the trained neural network. For example, control system 1602 may interpret a region of a sensed image (optical or acoustic) to be potentially anomalous. In this case, the actuator control command may be determined or selected to cause display 1606 to display the imaging and highlighting the potentially anomalous region.

In this embodiment, the control system 1602 would receive image and annotation information from sensor 1604. The control system 1602 may use the method described in FIG. 1 to formulate a prediction of the image received from sensor 1604. Based on this prediction, signals may be sent to actuator 1606, for example, to detect anomalous regions of the image or any of the actions performed by the actuator 1606 as described in the above sections.

The program code embodying the algorithms and/or methodologies described herein is capable of being individually or collectively distributed as a program product in a variety of different forms. The program code may be distributed using a computer readable storage medium having computer readable program instructions thereon for causing a processor to carry out aspects of one or more embodiments. Computer readable storage media, which is inherently non-transitory, may include volatile and non-volatile, and removable and non-removable tangible media implemented in any method or technology for storage of information, such as computer-readable instructions, data structures, program modules, or other data. Computer readable storage media may further include RAM, ROM, erasable programmable read-only memory (EPROM), electrically erasable programmable read-only memory (EEPROM), flash memory or other solid state memory technology, portable compact disc read-only memory (CD-ROM), or other optical storage, magnetic cassettes, magnetic tape, magnetic disk storage or other magnetic storage devices, or any other medium that can be used to store the desired information and which can be read by a computer. Computer readable program instructions may be downloaded to a computer, another type of programmable data processing apparatus, or another device from a computer readable storage medium or to an external computer or external storage device via a network.

Computer readable program instructions stored in a computer readable medium may be used to direct a computer, other types of programmable data processing apparatus, or other devices to function in a particular manner, such that the instructions stored in the computer readable medium produce an article of manufacture including instructions that implement the functions, acts, and/or operations specified in the flowcharts or diagrams. In certain alternative embodiments, the functions, acts, and/or operations specified in the flowcharts and diagrams may be re-ordered, processed serially, and/or processed concurrently consistent with one or more embodiments. Moreover, any of the flowcharts and/or diagrams may include more or fewer nodes or blocks than those illustrated consistent with one or more embodiments.

While all of the invention has been illustrated by a description of various embodiments and while these embodiments have been described in considerable detail, it is not the intention of the applicant to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of the general inventive concept.

What is claimed is:

1. A method of controlling a device comprising:
receiving data from a first sensor;
encoding, via parameters of an encoder, the data to obtain a latent observation (Wt) for the data and an uncertainty vector (sigma wt) for the latent observation;
processing the latent observation with a recurrent neural network to obtain a switching variable (St) which determines weights (alpha t) of a locally linear Kalman filter;
processing the latent observation and the uncertainty vector with said locally linear Kalman filter to obtain updated mean of latent representation (Mu and Sigma) and covariance of latent representation (Zt) of the Kalman filter;
decoding the latent representation to obtain mean and covariance of a reconstruction of the data; and
outputting the reconstruction at a time t.

2. The method of claim 1, wherein the weights of the locally linear Kalman filter are a function of the switching variable.

3. The method of claim 2, wherein the weights of the locally linear Kalman filter are a function of the switching variable expressed by
$${A}_{t} = {\sum }_{k = 1}^{K} {α}_{t}^{( k )} {A}^{( k )} ;$$
$${α}_{t} = ( {α}_{t}^{( 1 )} , … , {α}_{t}^{( K )} ) = softmax ( {s}_{t} ) ;$$
$${\sum }_{k = 1}^{K} {α}_{t}^{( k )} = 1 ;$$
$${α}_{t}^{( k )} \geq 0.$$

4. The method of claim 3, wherein the mean of latent representation (Mu and Sigma) and covariance of latent representation prior to a Kalman update are expressed by
p(zₜ|sₜ, zₜ₋₁)= [symbol] (μ_{z}_{ₜ}⁻, Σ_{z}_{ₜ}⁻)where μ_{z}_{ₜ}⁻=Aₜμ_{z}_{_{t−1}}⁺; Σ_{z}_{ₜ}⁻=AₜΣ_{z}_{_{t−1}}⁺Aₜ^{T}+I,σ^{trans}.

5. The method of claim 1, wherein an approximate posterior of the switching variables and latent states factorize according to
$$q ( {s}_{1 : T} , {z}_{1 : T} ) \vert {x}_{1 : T} ) = {{\prod }_{t = 1}}^{T} q ( {z}_{t} \vert {s}_{t} , {z}_{t - 1} , {x}_{t} ) q ( {s}_{t} \vert {s}_{< t} , {x}_{t} )$$
$$q ( {s}_{t} \vert {s}_{< t} , {x}_{t} ) = 𝒩 ( {μ}_{{s}_{t}} , {Σ}_{{s}_{t}} ) where$$
$$[ {μ}_{{s}_{t}} , {Σ}_{{s}_{t}} ] = {f}_{inf} ( {s}_{< t} , {x}_{t} ) .$$

6. The method of claim 1, wherein the data is time series data and the sensor is an optical sensor, an automotive sensor, or an acoustic sensor.

7. The method of claim 6, wherein the data is image data.

8. The method of claim 7 further including controlling a vehicle based on the reconstruction.

9. A device control system comprising:
a controller configured to,
receive data from a first sensor;
encode, via parameters of an encoder, the data to obtain a latent observation (Wt) for the data and an uncertainty vector (sigma wt) for the latent observation;
process the latent observation with a recurrent neural network to obtain a switching variable (St) which determines weights (alpha t) of a locally linear Kalman filter;
process the latent observation and the uncertainty vector with said locally linear Kalman filter to obtain updated mean (Mu and Sigma) and covariance of latent representation (Zt) of the Kalman filter;
decode the latent representation to obtain mean and covariance of a reconstruction of the data; and
output the reconstruction at a time t.

10. The device control system of claim 9, wherein the weights of the locally linear Kalman filter are a function of the switching variable.

11. The device control system of claim 10, wherein the weights of the locally linear Kalman filter are a function of the switching variable expressed by
$${A}_{t} = {\sum }_{k = 1}^{K} {α}_{t}^{( k )} {A}^{( k )} ;$$
$${α}_{t} = ( {α}_{t}^{( 1 )} , … , {α}_{t}^{( K )} ) = softmax ( {s}_{t} ) ;$$
$${\sum }_{k = 1}^{K} {α}_{t}^{( k )} = 1 ;$$
$${α}_{t}^{( k )} \geq 0.$$

12. The device control system of claim 11, wherein the mean of latent representation (Mu and Sigma) and covariance of latent representation prior to a Kalman update are expressed by
p(zₜ|sₜ, zₜ₋₁)=N(μ_{z}_{ₜ}⁻, Σ_{z}_{ₜ}⁻)where μ_{z}_{ₜ}⁻=Aₜμ_{z}_{_{t−1}}⁺; Σ_{z}_{ₜ}⁻=AₜΣ_{z}_{_{t−1}}⁺Aₜ^{T}+I,σ^{trans}.

13. The device control system of claim 9, wherein an approximate posterior of the switching variables and latent states factorize according to
$$q ( {s}_{1 : T} , {z}_{1 : T} ) \vert {x}_{1 : T} ) = {{\prod }_{t = 1}}^{T} q ( {z}_{t} \vert {s}_{t} , {z}_{t - 1} , {x}_{t} ) q ( {s}_{t} \vert {s}_{< t} , {x}_{t} )$$
$$q ( {s}_{t} \vert {s}_{< t} , {x}_{t} ) = 𝒩 ( {μ}_{{s}_{t}} , {Σ}_{{s}_{t}} ) where$$
$$[ {μ}_{{s}_{t}} , {Σ}_{{s}_{t}} ] = {f}_{inf} ( {s}_{< t} , {x}_{t} ) .$$

14. The device control system of claim 9, wherein the data is time series data and the sensor is an optical sensor, an automotive sensor, or an acoustic sensor.

15. The device control system of claim 14, wherein the data is image data.

16. The device control system of claim 9, wherein the device is a vehicle and the system controls acceleration and deceleration of the vehicle.

17. A system for processing time series data comprising:
an encoder configured to receive an observation and output an uncertainty vector and a latent observation;
a Kalman Update block configured to receive the uncertainty vector and latent observation and output a mean of the latent representation and a covariance of the latent representation;
a locally linear Kalman Filter configured to receive weights, the prior mean of the latent representation, and the prior covariance of the latent representation and output the posterior mean of the latent representation and posterior covariance of the latent representation;
an inference network configured to receive the latent observation and a deterministic recurrent cell, and output a switching variable and weights for the locally linear Kalman Filter;
a Gated Recurrent Unit configured to receive the switching variable and output the deterministic recurrent cell; and
a decoder configured to receive the latent representation and output a mean of the latent observation and a covariance of the latent observation.

18. The system of claim 17, wherein the inference network is configured to output weights of the of the locally linear Kalman filter as a function of the switching variable expressed by
$${A}_{t} = {\sum }_{k = 1}^{K} {α}_{t}^{( k )} {A}^{( k )} ;$$
$${α}_{t} = ( {α}_{t}^{( 1 )} , … , {α}_{t}^{( K )} ) = softmax ( {s}_{t} ) ;$$
$${\sum }_{k = 1}^{K} {α}_{t}^{( k )} = 1 ;$$
$${α}_{t}^{( k )} \geq 0.$$

19. The system of claim 18, wherein the locally linear Kalman filter is configured to output the prior mean of the latent representation and prior covariance of the latent representation as expressed by
p(zₜ|sₜ, zₜ₋₁)= [symbol] (μ_{z}_{ₜ}⁻, Σ_{z}_{ₜ}⁻)where μ_{z}_{ₜ}⁻=Aₜμ_{z}_{_{t−1}}⁺; Σ_{z}_{ₜ}⁻=AₜΣ_{z}_{_{t−1}}⁺Aₜ^{T}+I,σ^{trans}.

20. The system of claim 19, wherein the inference network is configured output a posterior mean of the switching variable and posterior covariance of the switching variable according to
q(sₜ|s_{<t}, xₜ)= [symbol] (μₛ_{ₜ}, Σₛ_{ₜ})where[μₛ_{ₜ}, Σₛ_{ₜ}]=f_{inf}(s_{<t}, xₜ)
